(19) United States
(12) Patent Application Publication
(10) Pub. No.: US 2007/0013050 A1
(43) Pub. Date: Jan. 18, 2007

(54) Structure of an over-current protection device and method for manufacturing the same

(75) Inventors: Ching-Chien Chen, Zhunan Town (TW); Kun-Huang Chang, Zhunan Town (TW); Yi-Wen Chen, Zhunan Town (TW)

Correspondence Address: LADAS & PARRY, 26 WEST 61ST STREET, NEW YORK, NY, 10023, US

(73) Assignee: INPAQ TECHNOLOGY CO., LTD.

(21) Appl. No.: 11/396,197

(22) Filed: Mar. 31, 2006

(30) Foreign Application Priority Data
Jul. 15, 2005 (TW) 094124019

(51) Int. Cl. H01L 23/00

(52) U.S. Cl. 257/703

(57) ABSTRACT

This invention is novel structure of an over-current protection device and manufacturing method thereof. The over-current protection device is formed with a main body with a lead frame and a ceramic fiber lead wound by a metal wire exteriorly, by coating the exterior of the whole lead with a thermally-insulating material, and then cladding the lead with a flame retardation material having an electrical insulation characteristic.

### BACKGROUND OF THE INVENTION

1. Field of the Invention

The present invention relates to a method of manufacturing an over-current protection device, especially an over-current protection device configured by forming a main body structure with a lead frame and a ceramic fiber lead wound by a metal wire, coating the exterior of the whole lead part with a heat-insulating material, and then cladding it with a flame retardation material with an electrical insulation characteristic.

2. Description of the Prior Art

In general, an over-current protection device used in telecommunication equipment is a telecommunication equipment protection fusible fuse (TEPFF), or called a telecommunication equipment protection module (TEPM).

A conventional over-current protection device, which employs a fusible fuse to protect telecommunication equipment against damage caused by over current, is required to be of very high quality. Such an over-current protection device with a fusible fuse is generally formed by winding a ceramic fiber lead around a metal wire, then connecting the fiber to an external electrode through a tin sheet, placing the fiber in a ceramic pipe with vacuum pumping and filling the pipe with an inert gas. However, during manufacturing of such a structure, a special furnace is necessary for vacuum pumping, filling the pipe with inert gas and connecting the tin sheet to the external electrode. The electrode needs to be connected to the ceramic fiber lead wound by a metal wire interiorly using the tin sheet by high-temperature melting, so that the process becomes difficult to control and its product yield is limited.

Moreover, the ceramic pipe of the aforementioned over-current protection device with a fusible fuse is filled with an inert gas. Thus, for this over-current protection device with a fusible fuse, when a high-energy inrushing current occurs during manufacturing, the ceramic pipe may explode due to instant expansion of the interior inert gas, causing a potential risk in use.

### SUMMARY OF THE INVENTION

In view of the above-mentioned shortcomings of the conventional over-current protection device with a fusible fuse, the present invention is intended to provide a novel structure of an over-current protection device and manufacturing method thereof. The over-current protection device according to the present invention doesn't need to be filled with inert gas, nor does it need a tin sheet to be connected to an external electrode; thus, its manufacture is simple, and the process and the yield are easy to control, thereby reducing the manufacturing cost, which is an object of the present invention.

The over-current protection device according to the invention is configured by forming a main body structure by clamping a lead frame and a ceramic fiber lead wound by a metal wire exteriorly, coating the exterior of the main body structure with a heat-insulating material, then cladding it with a flame retardation material with an electrical insulation characteristic, and finally clamping a U-shaped frame with a T-shaped end for surface adhesion or soldering. It is of high and stable quality and suitable for many special applications, which is another object of the invention.

In accordance with the over-current protection device, it is yet another object of the present invention that the above-mentioned construct will not cause a short circuit due to melting of the metal layer material on the surface under large amounts of heat energy generated when high voltage and high current are passing by.

The detailed structure, manufacturing method and other objects and functions can be fully understood by the description below with reference to the accompanying

### BRIEF DESCRIPTION OF THE DRAWINGS

FIG. 1 is a three-dimensional diagram of the present invention.

FIG. 2 is a longitudinal sectional view of the present invention.

### LIST OF REFERENCE NUMERALS

10 main body

11 lead frame

12 ceramic fiber lead

13 metal wire

14 heat-insulating material

15 flame retardation material

### DETAILED DESCRIPTION

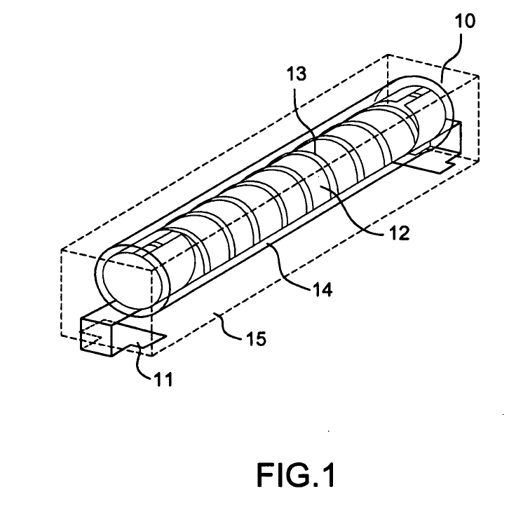

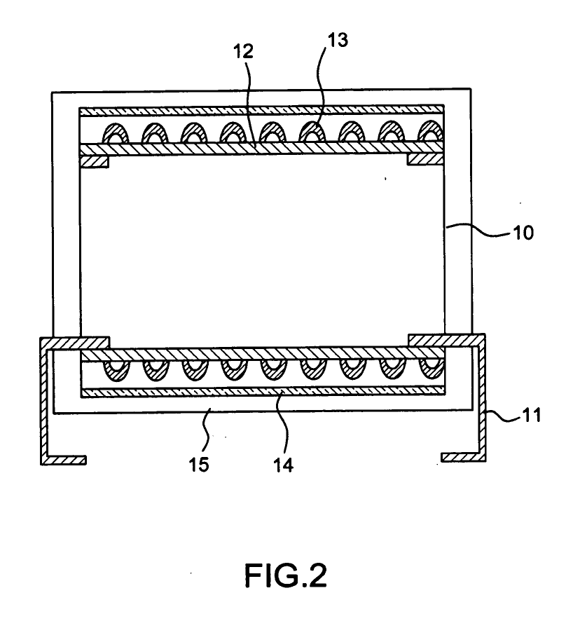

The new structure of the over-current protection device of the invention and the manufacturing method is exemplified by TEPFF as shown in FIGS. 1 and 2, substantially configured by forming a main body 10 by a lead frame 11 and a ceramic fiber lead 12 wound by a metal wire 13 exteriorly, coating the exterior of the lead 12 with a thermally-insulating material 14 such as sodium silicate, and then cladding the main body 10 with a flame retardation material 15 of an electrical insulation characteristic through injection molding or hot pressing. The frame 11 may be U-shaped as shown in FIG. 2, wherein one end of the U-shaped frame is T-shaped as shown in FIG. 1.

The purpose of adopting a ceramic fiber as the matrix of the lead is to absorb the melted liquid metal caused by the melting of the metal layer material due to large amounts of heat energy generated when high voltage and high current are passing by, thereby avoiding a short circuit.

The manufacturing manner of the over-current protection device according to the present invention may be of the batch type or automatic continuous type, which will be described in detail with embodiments hereinafter:

Embodiment 1

Steps of the batch type manufacturing manner are as follows:
1. Putting a finished ceramic fiber lead wound by a metal wire and a lead frame in a mould of predetermined dimensions, and connecting the lead frame to the metal wire;
2. After coating the exterior of the lead with a thermally-insulating material such as sodium silicate, forming an over-current protection device having a main body formed by a lead frame and a ceramic fiber lead wound by the metal wire by hot pressing.
3. While making the device, suction must be performed to form a vacuum state, so that water and small molecular materials dissolved due to heat during a heating process are removed. The suction can prevent the main body from forming voids if the water and small molecular materials remain in the cladding material, which will weaken the structural strength of the main body; on the other hand, the suction can get rid of water remaining in the structural layer of the cladding material so as to protect the electrical insulation characteristic of the finished product.

The cladding material may be selected from plastic materials which can be extruded. To make a compromise between the fluidity of formula materials formulated in the molding processing and the structural strength of the finished products, a preferred melting index of the plastic materials should be in the range of 0.3 to 1.0.

Embodiment 2

Steps of automatic continuous type manufacturing are as follows:
1. Putting a finished ceramic fiber lead wound by a metal wire and a lead frame in a reel-type carrier of predetermined dimensions, and connecting the lead frame to the wire;
2. After coating the exterior of the lead with a thermally-insulating material such as sodium silicate, making an over-current protection device having a main body formed by a lead frame and a ceramic fiber lead wound by a metal wire exteriorly, by using injection molding in conjunction with an automatic feeding mechanism. A mold should have exhaust holes for exhausting gases during the manufacturing of the finished products, so that water and small molecular materials dissolved due to heat during a heating process are removed, to prevent forming voids if the water and small molecular materials remain in the structural layer of the cladding material, which will weaken the structural strength of the main body; on the other hand, the suction can get rid of water remaining in the structural layer of the cladding material so as to protect the electrical insulation characteristic of the finished product.

A plastic material selected for the cladding material must be of injection molding level. To make a compromise between the fluidity of formula materials formulated in the mold and the structural strength of the finished products, a preferable melting index of the plastic material should be in the range of 3 to 8.

Suitable plastic materials include polypropylene (PP), high-density polyethylene (HDPE), polystyrene (PS), acrylnitrile-styrene (AS), acrylnitrile-butadiene-styrene (ABS), polycarbonate (PC), PC/ABS blend, polyester (PET/PBT), polyether (poly-phenyl-oxide: PPO, poly-phenyl-ether: PPE), poly-phenyl-sulfone (PPS), polyamide (PA6, PA66), polyimide (PI), liquid crystal polymers (LCP), silicone rubber, and so on.

To increase the structural strength of the cladding material, a proper chopped glass fiber can be added to the cladding material for reinforcement.

Due to the addition of the glass fiber to the formula of the cladding material, a surface fiber floating phenomena may occur during the process of formation. To improve the appearance and the convenience of the standard printing, a little carbon black used in dyeing can be added to the formula of the cladding material, or a color master-batch pellet can be directly adopted to dye the cladding material. However, it should be noted that excessive addition will have an impact on the electrical insulation characteristic of the cladding material.

To improve the flame retardation characteristic of the cladding material to reach the fire test standard (UL94 V2-V0), suitable arc-controlling agents can be added. Once heated in oxygen deficient environments, such a cladding material will generate gaseous by-products, such as H₂O, CO₂, and N₂. These materials are, for example, hydrated metal oxide, or other hydrated inorganic materials, especially Al(OH)₃ 3H₂O or Mg(OH)₂2H₂O.

Further, to improve the electrical insulation characteristic of the cladding material, a proper filler, such as CaCO₃, clay, talc, mica, kaolin, silica, wollastonite and the like, can be added. Moreover, a suitable coupling agent can be added to improve the dispersing effect of the filler and the adhesion between the filler and the plastic matrix.

During the overall manufacturing process, a small number of additives will be added to improve the processing stability of the formula materials. The additives are, for example, antioxidants, and lubricant such as wax or stearates such as calcium stearate, and the like.

To enable such a product to function properly as a protection device even under a higher voltage (Vmax≧600 Volts), a peroxide can be employed in the cladding material. Once heated, the peroxide will decompose to generate free radicals, which attack the main chain of the plastic material to form cross-linking. Alternatively, silicone can cause cross-linking by decomposition in water. Also, electron-beam radiation or a/an γ-ray generated by a cobalt irradiation source 60 can be used to form cross-linking, so as to improve the performance characteristic resistant to high voltages. To meet the requirement of this electrical characteristic, the dosage of the radiation may be controlled within only 30 Mrad inclusive. A cross-linking auxiliary containing a polyfunctional group, for example, triallyl-isocyanurate (TAIC), can be added to enhance the cross-linking effect.

An example of the formula of the cladding material:

| | | |
|---|---|---|
| HDPE | 60 | wt % |
| chopped glass fiber | 15 | wt % |
| arc-controlling agent | 25 | wt % |
| antioxidant | 1 | wt % |
| lubricant | 3 | phr |
| cross-linking auxiliary | 3 | phr |
| coupling agent | 3 | phr |

Since the aforementioned over-current protection device is provided with a lead frame, it can be placed directly in a fixed position on a circuit board, instead of first placing a frame in the fixed position on the circuit board and then soldering the main body of the device onto the frame, thereby improving the availability of the over-current protection device. The exterior of the main body of the invention is coated with a thermally-insulating material such as sodium silicate, to provide an excellent insulation characteristic. Moreover, the ceramic fiber is used as the matrix of the lead, so that the melted metal caused by the melting of the metal wire due to large amount of heat energy generated when high voltage and high current are passing by can be absorbed, thereby avoiding a short circuit. The entire structure and the manufacturing method thereof are unprecedented and meet the provision of the patent law.

It should be understood that the embodiments as described above are only preferred embodiments of the present invention. Modifications made according to the concept of the present invention and their functions do not depart from the spirit of the present invention covered by the specification and the drawings and should be included within the scope of the claims.

What is claimed is:

1. An over-current protection device, comprising:
a main body, including a lead frame, a metal wire and a ceramic fiber lead, wherein the metal wire is used to wind around the ceramic fiber lead;
a thermally-insulating material for coating the ceramic fiber lead; and
a flame retardation material for partly cladding the ceramic fiber lead.

2. The device according to claim 1, further comprising a U-shaped frame disposed on the flame retardation material, for surface mounting or soldering.

3. The device according to claim 1, wherein the thermally-insulating material is sodium silicate.

4. The device according to claim 1, wherein the flame retardation material is electrically insulative.

5. The device according to claim 1, wherein one end of the U-shaped frame is T-shaped.

6. The device according to claim 1, wherein the flame retardation material has a melting index preferably in the range of 0.3 to 8.

7. The device according to claim 4, wherein the flame retardation material has a melting index preferably in the range of 0.3 to 8.

8. The device according to claim 1, wherein the flame retardation material can be selected from one of a polypropylene, a high-density polyethylene, a polystyrene, an acrylnitrile-styrene, an acrylnitrile-butadiene-styrene, a polycarbonate, a PC/ABS blend, a polyester, a polyether, a polyphenylene, a polyamide, a polyimide, a liquid crystal polymer or a silicone rubber, or a combination thereof.

9. The device according to claim 4, wherein the flame retardation material can be selected from one of a polypropylene, a high-density polyethylene, a polystyrene, an acrylnitrile-styrene, an acrylnitrile-butadiene-styrene, a polycarbonate, a PC/ABS blend, a polyester, a polyether, a polyphenylene, a polyamide, a polyimide, a liquid crystal polymer or a silicone rubber, or a combination thereof.

10. The device according to claim 1, wherein the flame retardation material comprises a chopped glass fiber to reinforce the structural strength.

11. The device according to claim 1, wherein the flame retardation material comprises a carbon black for dyeing or a color master-batch pellet for dyeing.

12. The device according to claim 10, wherein the flame retardation material comprises a carbon black for dyeing or a color master-batch pellet for dyeing.

13. The device according to claim 1, wherein the flame retardation material comprises an arc-controlling agent to improve the fire protection effect.

14. The device according to claim 4, wherein the flame retardation material comprises an arc-controlling agent to improve the fire protection effect.

15. The device according to claim 1, wherein the flame retardation material comprises a filler selected from one of a calcium carbonate, a clay, a talc, a mica, a kaolin, a silica, a wollastonite, or a combination thereof, to enhance its electrical insulation characteristic.

16. The device according to claim 4, wherein the flame retardation material comprises a filler selected from one of a calcium carbonate, a clay, a talc, a mica, a kaolin, a silica, a wollastonite, or a combination thereof, to enhance its electrical insulation characteristic.

17. The device according to claim 15, wherein the flame retardation material further comprises a coupling agent, to improve a dispersing effect of the filler and adhesion between the filler and the flame retardation material.

18. The device according to claim 16, wherein the flame retardation material further comprises a coupling agent, to improve a dispersing effect of the filler and adhesion between the filler and the flame retardation material.

19. The device according to claim 15, wherein the flame retardation material further comprises a small amount of additives selected from one of an antioxidant, a lubricant and a stearate, or a combination thereof, to improve stability of the flame retardation material, wherein the lubricant can be a wax and the stearate can be a calcium stearate.

20. The device according to claim 16, wherein the flame retardation material further comprises a small amount of additives selected from one of an antioxidant, a lubricant and a stearate, or a combination thereof, to improve stability of the flame retardation material, wherein the lubricant can be a wax and the stearate can be a calcium stearate.

21. The device according to claim 15, wherein the flame retardation material further comprises a peroxide or a silicone, and the peroxide and the silicone will generate a cross-linking effect to improve voltage resistance of the protection device.

22. The device according to claim 16, wherein the flame retardation material further comprises a peroxide or a silicone, and the peroxide and the silicone will generate a cross-linking effect to improve voltage resistance of the protection device.

23. The device according to claim 21, wherein the flame retardation material further comprises a cross-linking auxiliary with a polyfunctional group to improve the cross-linking effect, wherein the cross-linking auxiliary can be triallyl-isocyanurate.

24. The device according to claim 22, wherein the flame retardation material further comprises a cross-linking auxiliary with a polyfunctional group to improve the cross-linking effect, wherein the cross-linking auxiliary can be triallyl-isocyanurate.

25. The device according to claim 1, wherein the flame retardation material comprises a high density polyethylene by 60 wt %, a chopped glass fiber by 15 wt %, an arc-controlling agent by 25 wt %, an antioxidant by 1 wt %, a lubricant by 3 phr and a cross-linking auxiliary agent by 3 phr.

26. The device according to claim 4, wherein the flame retardation material comprises a high density polyethylene by 60 wt %, a chopped glass fiber by 15 wt %, an arc-controlling agent by 25 wt %, an antioxidant by 1 wt %, a lubricant by 3 phr and a cross-linking auxiliary agent by 3 phr.

27. A method for making an over-current protection device, comprising the following steps:
(a) providing a ceramic fiber with two ends as a matrix of a lead to form a ceramic fiber lead;
(b) plating the ceramic fiber lead with a layer of metal wire;
(c) disposing the ceramic fiber lead on a lead frame and clamping the two ends of the ceramic fiber lead on the lead frame for the first time to fix the ceramic fiber lead;
(d) coating the ceramic fiber lead with a thermally-insulating material; and
(e) coating the ceramic fiber lead with a flame retardation material.

28. The method according to claim 27, further comprising clamping of the two ends of the ceramic fiber on the lead frame for the second time to form a U-shaped frame.

29. The method according to claim 27, wherein the metal wire is spiral-shaped.

30. The method according to claim 27, wherein the thermally-insulating material is a sodium silicate.

31. The method according to claim 27, wherein the flame retardation material has an electrical insulation characteristic.

32. The method according to claim 27, wherein one end of the U-shaped frame is T-shaped.

33. The method according to claim 27, wherein the step of cladding the ceramic fiber lead is done by injection molding or hot pressing.

34. The method according to claim 27, further comprising the step of exhausting gases.

35. The method according to claim 27, wherein the flame retardation material has a melting index preferably in the range of 0.3 to 8.

36. The method according to claim 27, wherein the flame retardation material can be selected from one of a polypropylene, a high-density polyethylene, a polystyrene, an acrylnitrile-styrene, an acrylnitrile-butadiene-styrene, a polycarbonate, a PC/ABS blend, a polyester, a polyether, a polyphenylene, a polyamide, a polyimide, a liquid crystal polymer or a silicone rubber, or a combination thereof.

37. The method according to claim 27, wherein the flame retardation material comprises a chopped glass fiber to reinforce its structural strength.

38. The method according to claim 27, wherein the flame retardation material comprises a carbon black for dyeing or a color master-batch pellet for dyeing.

39. The method according to claim 27, wherein the flame retardation material comprises an arc-controlling agent to improve the fire protection effect.

40. The method according to claim 27, wherein the flame retardation material comprises a filler selected from one of a calcium carbonate, a clay, a talc, a mica, a kaolin, a silica, a wollastonite, or a combination thereof, to enhance its electrical insulation characteristic.

41. The method according to claim 40, wherein the flame retardation material further comprises a coupling agent to increase a dispersing effect of the filler and adhesion between the filler and the flame retardation material.

42. The method according to claim 40, wherein the flame retardation material further comprises a small amount of additives selected from one of an antioxidant, a lubricant and a stearate, or a combination thereof, to improve the processing stability of the flame retardation material, wherein the lubricant can be a wax and the stearate can be a calcium stearate.

43. The method according to claim 40, wherein the flame retardation material further comprises a peroxide or a silicone for improving voltage resistance of the protection device, wherein once heated, the peroxide will decompose to generate free radicals, which attack a main chain of the plastic material so as to form cross-linking, and the silicone causes cross-linking by decomposition in water.

44. The method according to claim 40, further comprising the step of using an electron beam or an γ-ray generated by irradiation source cobalt 60 to radiate the flame retardation material to form cross-linking, so as to improve the voltage resistance of the protection device.

45. The method according to claim 43, wherein the flame retardation material further comprises a cross-linking auxiliary with a polyfunctional group to improve the cross-linking effect, wherein the cross-linking auxiliary can be triallyl-isocyanurate.

46. The method according to claim 27, wherein the flame retardation material comprises a high-density polyethylene by 60 wt %, a chopped glass fiber by 15 wt %, an arc-controlling agent by 25 wt %, an antioxidant by 1 wt %, a lubricant by 3 phr and a cross-linking auxiliary by 3 phr.

47. The method according to claim 27, wherein when the method is operated in a batch type, the method further comprises the following steps:
(a) putting the ceramic fiber lead fixed on the lead frame according to the steps (a), (b) and (c) of claim 27 on a mold of predetermined dimensions;
(b) coating the lead with a thermally-insulating material such as sodium silicate, and then manufacturing an over-current protection device of the ceramic fiber lead coated with a flame retardation material and fixed on the lead frame, by hot pressing; and
(c) while making the device, exhausting gases from the device to form a vacuum state, so that water may get out.

48. The method according to claim 47, wherein the flame retardation material has a melting index preferably in the range of 0.3 to 1.0.

49. The method according to claim 27, wherein when the method is operated in automatic continuous type, the method further comprises the following steps:
(a) putting the ceramic fiber lead fixed on the lead frame according to the steps (a), (b) and (c) of claim 27 on a reel of predetermined dimensions; and
(b) coating the lead with a thermally-insulating material such as sodium silicate, and then making an over-current protection device of the ceramic fiber lead coated with a flame retardation material and fixed on the lead frame, by injection molding in conjunction with an automatic-feeding mechanism;
c. providing exhaust holes in a mold to enable the over-current protection device to exhaust gases during the manufacturing process.

50. The method according to claim 49, wherein the flame retardation material has a melting index preferably in the range of 3 to 8.
